(19) United States
(12) Patent Application Publication
(10) Pub. No.: US 2024/0334652 A1
(43) Pub. Date: Oct. 3, 2024

(54) HEAT DISSIPATION DEVICE AND PROCESSING METHOD OF HEAT DISSIPATION DEVICE

(71) Applicants: CHAMP TECH OPTICAL (FOSHAN) CORPORATION, Foshan (CN); Foxconn Technology Co., Ltd., New Taipei (TW)

(72) Inventors: MENG FU, Foshan (CN); WAN-HUA LEI, Foshan (CN); RUI-ZE WU, Foshan (CN)

(21) Appl. No.: 18/513,943

(22) Filed: Nov. 20, 2023

(30) Foreign Application Priority Data
Mar. 27, 2023 (CN) 202320637959.0

(51) Int. Cl. H05K 7/20

(52) U.S. Cl. CPC H05K 7/20336; H05K 7/2039

(57) ABSTRACT

A heat dissipation device, comprising a heat-conducting component and a plurality of heat fins, wherein the heat-conducting component comprises a heat pipe, each heat fins comprises a heat dissipation plate and a folding edge, the heat dissipation plate defines on a through-hole, the folding edge is arranged around an edge of the through-hole, the folding edge protrudes from one side of the heat dissipation plate, an extension wall is provided at the folding edge far away from an end of the heat dissipation plate, the extension wall extends from the folding edge to a side away from the heat pipe, the folding edge is spaced from the heat pipe, a gap is defined between the heat pipe and a circumference of the heat pipe, the extension wall is spaced from the circumference of the heat pipe to form a first containment chamber.

### FIELD

The present disclosure relates to field of heat dissipation technology, particularly to a heat dissipation device and a processing method of a heat dissipation device.

### BACKGROUND

Radiators dissipate heat from the heat source. Existing radiators include a heat pipe and heat fins, and the heat pipe and the heat fins are connected by solder paste welding. The existing radiators have a problem of poor welding of heat pipes and heat fins, such as pores in the welding between heat pipes and heat fins.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 illustrates a stereogram of a heat dissipation device according to an embodiment of the present disclosure.

FIG. 2 illustrates a stereogram of the heat dissipation device in FIG. 1 from another angle.

FIG. 3 illustrates a partially cross-sectional view of the heat dissipation device in FIG. 2 along the III-III line.

FIG. 4 illustrates an enlarged view of the heat dissipation device in FIG. 3 in IV region.

FIG. 5 illustrates an exploded view of the heat dissipation device in FIG. 1.

FIG. 6 illustrates a flowchart of a processing method of a heat dissipation device according to an embodiment of the present disclosure.

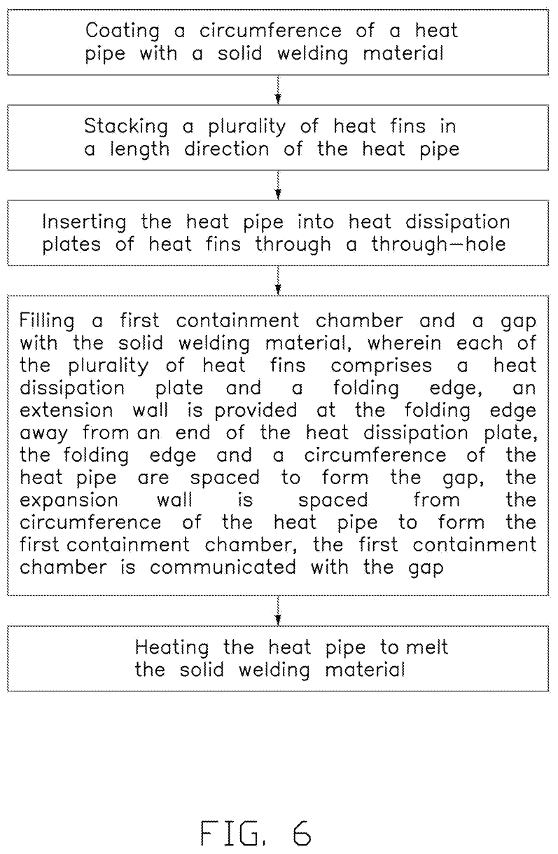

### DETAILED DESCRIPTION

In order to make the above-mentioned objects, features and advantages of the present application more obvious, a detailed description of specific embodiments of the present application will be described in detail with reference to the accompanying drawings. A number of details are set forth in the following description so as to fully understand the present application. However, the present application can be implemented in many other ways different from those described herein, and those skilled in the art can make similar improvements without violating the contents of the present application. Therefore, the present application is not to be considered as limiting the scope of the embodiments described herein.

Several definitions that apply throughout this disclosure will now be presented.

The term “coupled” is defined as coupled, whether directly or indirectly through intervening components, and is not necessarily limited to physical connections. The connection may be such that the objects are permanently coupled or releasably coupled. The term “substantially” is defined to be essentially conforming to the particular dimension, shape, or other feature that the term modifies, such that the component need not have that exact feature. The term “comprising,” when utilized, means “including, but not necessarily limited to;” it specifically indicates open-ended inclusion or membership in the so-described combination, group, series, and the like.

Unless otherwise defined, all technical and scientific terms used herein have the same meaning as commonly understood by one skilled in the art. The terms used in a specification of the present application herein are only for describing specific embodiments and are not intended to limit the present application. The terms “and/or” used herein includes any and all combinations of one or more of associated listed items.

Some embodiments of the present application are described in detail. In the case of no conflict, the following embodiments and the features in the embodiments can be combined with each other.

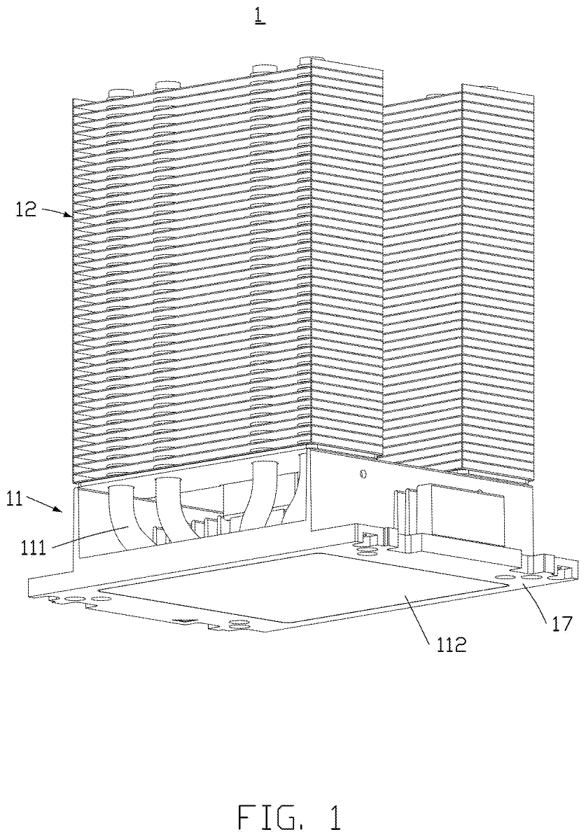

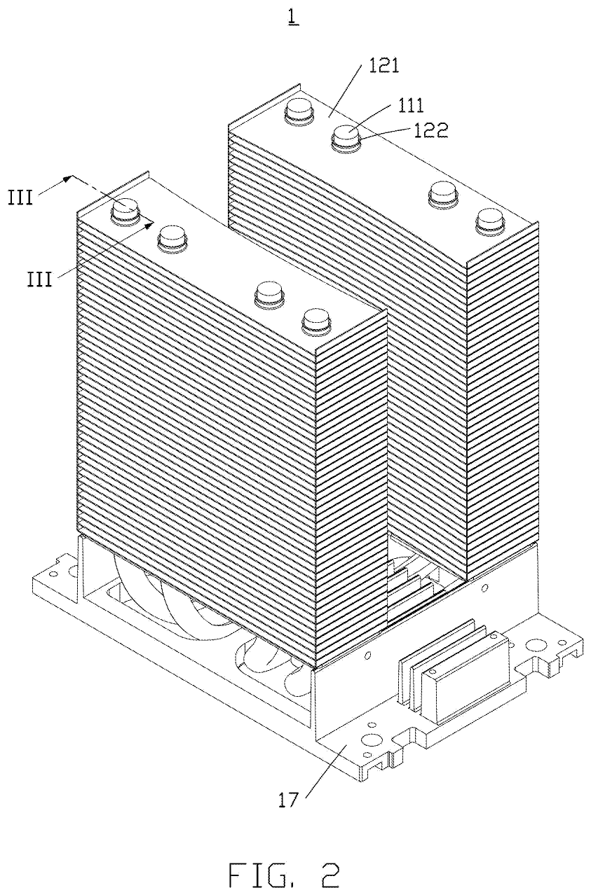

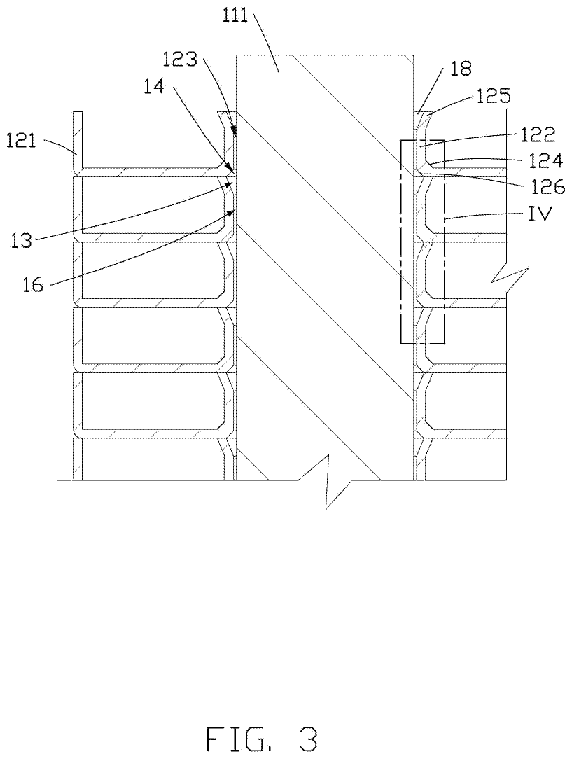

Referring to FIG. 1, FIG. 2, and FIG. 3, an embodiment of the present application discloses a heat dissipation device 1. The heat dissipation device 1 is installed on a surface of a heat source (such as a Central Processing Unit (CPU) or other electronic devices) to dissipate heat. The heat dissipation device 1 includes a heat-conducting component 11, a plurality of heat fins 12 and a holder 17. The heat fins 12 are positioned on the holder 17. The heat-conducting component 11 includes one or more heat pipe 111. Part of the heat pipe 111 is positioned in the heat fins 12. The heat pipe 111 transfers heat from the heat source to the heat fins 12. Each of the heat fins 12 includes a heat dissipation plate 121 and a folding edge 122. The heat dissipation plate 121 defines on a through-hole 123 for the heat pipe 111 to pass through. The folding edge 122 is arranged around an edge of the through-hole 123. The folding edge 122 is protruded from one side of the heat dissipation plate 121, and an end of the folding edge 122 away from the heat dissipation plate 121 is provided with an expansion wall 125. The expansion wall 125 is inclined to an axis of the heat pipe 111. The expansion wall 125 is extended away from the heat pipe 111. A circumferential surface of the folding edge 122 is spaced from a circumference of the heat pipe 111 to form a gap 16. The expansion wall 125 is spaced from the circumference of the heat pipe 111 to form a first containment chamber 13. The first containment chamber 13 is communicated with the gap 16.

In one embodiment, when the heat fins 12 are welded with the heat pipe 111 by the welding material 18. In a welding process, the first containment chamber 13 and the gap 16 are filled with a solid welding material 18, and then the heat dissipation device 1 is heated to melt the welding material 18. Since the expansion wall 125 is extended away from one side of the heat pipe 111, a section width of the first containment chamber 13 is larger than a width of the gap 16, and more welding material 18 can be accommodated in the first containment chamber 13. The section width and a height of the first containment chamber 13 are larger, the welding material 18 by melting in the first containment chamber 13 can flow downward to the gap 16 under the action of gravity. Bubbles in the gap 16 reduces during flowing process of the welding material 18. A connection area of the welding material 18 in the gap 19 between the heat pipe 111 and the heat fins 12 is also increased. Therefore, there are fewer bubbles in the gap 16 after welding, the heat pipe 111 and the heat fins 12 are welded reliably, and the heat dissipation effect is guaranteed.

The folding edge 122 is a ring-shaped structure, and the folding edge 122 sleeves around a circumference of the heat pipe 111. The folding edge 122 is connected to the heat dissipation plate 121 to increase the connection area of the welding material 18 between the heat fins 12 and the heat pipe 111. Therefore, a heat transfer efficiency of the heat pipe 111 to the heat dissipation plate 121 can be improved. Furthermore, the heat dissipation plate 121 can increase the connection area of the welding material 18 by folding edge 122, and the heat dissipation plate 121 can improve a fixed strength of the heat dissipation plate 12 and the heat pipe 111 by folding edge 122. The heat dissipation plate 121 and the heat pipe 111 are stably and firmly connected together.

In one embodiment, each of the heat fins 12 is stacked and spaced in a length direction of the heat pipe 111.

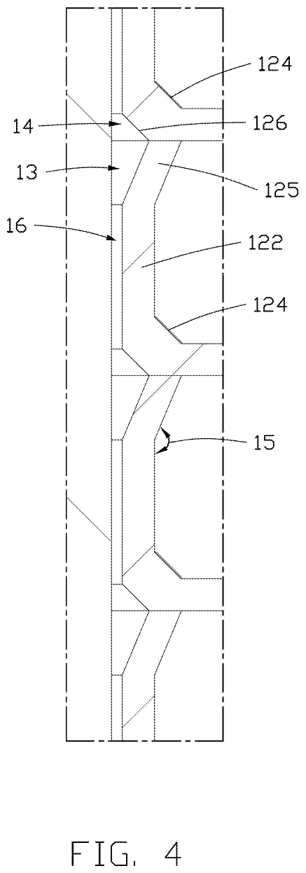

Referring to FIG. 4, a chamfer 124 is provided between the folding edge 122 and the heat dissipation plate 121, and the chamfer 124 is spaced from a circumference of the heat pipe 111 to form a second containment chamber 14, and the second containment chamber 14 is communicated with the gap 16.

In one embodiment, the chamfer 124 of a heat fins 12 is in contact with an extension wall 125 of an adjacent heat fins 12. The second containment chamber 14 of the heat fins 12 is communicated with the first containment chamber 13 of the adjacent heat fins 12.

The folding edge 122 is extended in the length direction of the heat pipe 111, the folding edge 122 is connected between the expansion wall 125 and the chamfer 124, the folding edge 122 relates to the expansion wall 125 and the chamfer 124. The welding material 18 in the first containment chamber 13 and the second containment chamber 14 flows to the gap 16 after hot melting, the welding material 18 can be fully filled in the gap 16, so that the folding edge 122 and the heat pipe 111 are well welded and tightly connected.

The chamfer 124 is inclined to intersect the folding edge 122, when heat pipe 111 is inserting into through-hole 123, the chamfer 124 or the expansion wall 125 can guide the heat pipe 111 into the through-hole 123. The chamfer 124 of a heat fin 12 can correspond to the expansion wall 125 of an adjacent heat fin 12, a closed space can be formed between two adjacent heat fins 12.

In one embodiment, a section shape 126 can be triangular. The section shape 126 is formed between the chamfer 124 of the heat fin 12, the expansion wall 125 of the adjacent heat fin 12, and a circumference of the heat pipe 111.

In one embodiment, a width of the gap 16 is 0.1 mm˜0.5 mm.

In one embodiment, the gap 16 is formed between the folding edge 122 and the circumference of the heat pipe 111, and a molten welding material 18 flows to the gap 16 from the first containment chamber 13 and the second containment chamber 14 under an action of capillary force. A distance between the folding edge 122 and the circumference of the heat pipe 111 can be 0.1 mm, 0.25 mm, and 0.5 mm. In some embodiments, the distance between the folding edge 122 and the circumference of the heat pipe 111 is 0.25 mm, the welding material 18 can flow smoothly between the folding edge 122 and the heat pipe 111.

In one embodiment, the folding edge 122 is intersected obliquely with the extension wall 125 to form a first angel 15, and the first angle 15 is 130°˜140°.

In one embodiment, the expansion wall 125 intersects the folding edge 122 at an oblique angle to form a funnel shape. The welding material 18 in the first containment chamber 13 fully fills the gap 16.

The first angle 15 is 130°˜140°, such as 130°, 135° or 140°. In other embodiments, the first angle 15 is 135. The first containment chamber 13 is formed between the expansion wall 125 and the folding edge 122.

In one embodiment, a length of the folding edge 122 is 1 mm˜1.5 mm, liquid welding material 18 can flow from the first containment chamber 13 and the second containment chamber 14 to the gap 16 under the action of capillary forces. The bubble is also easy to flow from the gap 16 to the first containment chamber 13 and the second containment chamber 14, the gap 16 is filled with welding material 18. In other embodiments, the length of the folding edge 122 is 1.2 mm, the liquid welding material 18 has good fluidity.

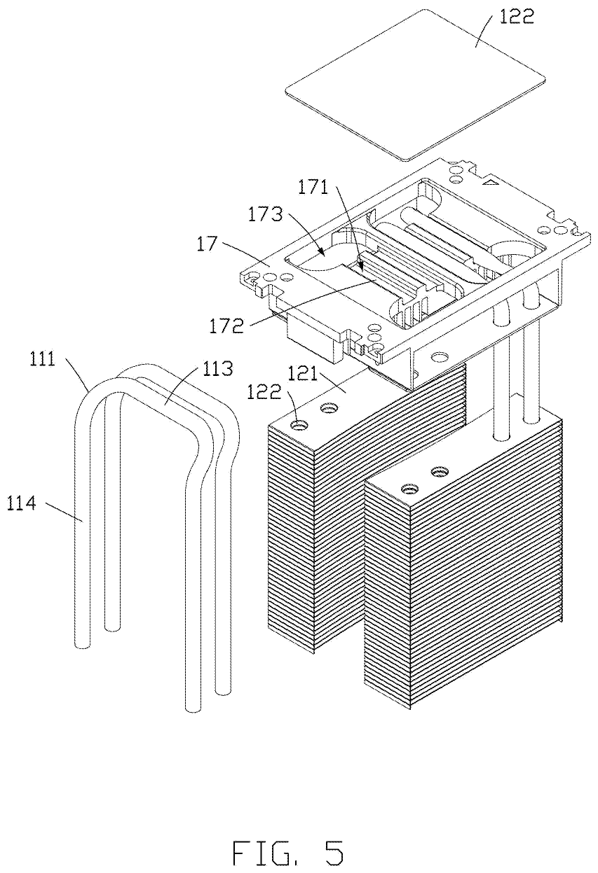

Referring to FIG. 5, the heat-conducting component 11 also includes a heat-conducting plate 112 and plurality of the heat pipes 111, including the heat pipe 111, and the plurality of heat pipes 111 is thermally coupled to the heat-conducting plate 112.

In one embodiment, the heat-conducting plate 112 can be a flat plate, and the heat-conducting plate 112 is connected to multiple heat pipes 111, and the heat-conducting plate 112 conducts heat to the heat pipe 111 to balance a heat dissipation efficiency among multiple heat pipes 111. The heat-conducting plate 112 can improve an overall heat dissipation performance of the heat dissipation device 1.

In one embodiment, the heat pipe 111 comprises a heat-conducting portion 113 and two heat dissipation portions 114. Two heat dissipation portions 114 are connected to both ends of the heat-conducting portion 113, and the holder 17 defines on a storage groove 171. A bottom surface 172 of the storage groove 171 defines on a penetration hole 173 along the thickness direction of the holder 17. The heat-conducting portion 113 is matched with the bottom surface 172, the heat dissipation portion 114 is extended from the storage groove 171 toward the heat fins 12 by the penetration hole 173.

In one embodiment, the holder 17 supports a plurality of heat pipes 111 and heat fins 12, the folding edge 122 is stably connected to the heat pipe 111 by the holder 17 to maintain a good heat transfer performance.

In other embodiments, the holder 17 is omitted, and the heat-conducting plate 112 is connected directly to an electronic device.

The heat-conducting portion 113 of the heat pipe 111 is flat, the heat pipe 111 can be fully in contact with a surface of the heat-conducting plate 112 to increase a heat-conducting rate between the heat pipe 111 and the heat-conducting plate 112. The heat dissipation portion 114 of the heat pipe 111 extends towards the heat fins 12, and the heat dissipation portion 114 is welded together with the heat fins 12. Heat absorbed by the heat-conducting portion 113 is transferred to the heat fins 12 by the heat pipe 111.

In one embodiment, before the heat-conducting component 11 and the heat fins are installed to the holder 17, a circumference of the heat pipe 111 of the heat-conducting component 11 is coated with the solid welding material 18. Then a plurality of heat fins 12 is stacked in the length direction of the heat pipe 111, the heat pipe 111 is inserted into heat dissipation plates 121 of heat fins 12 through a through-hole 124, and the first containment chamber 13 and the gap 16 are filled with the solid welding material 18. Finally, the heat pipe 111 is heated to melt the welding material 18.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A heat dissipation device, comprising:
a heat-conducting component, comprising a heat pipe; and
a plurality of heat fins, each comprising a heat dissipation plate and a folding edge, a through-hole is defined on the heat dissipation plate, the heat pipe passed through the through-hole, the folding edge is arranged around an edge of the through-hole, the folding edge protrudes from one side of the heat dissipation plate, an extension wall is provided at the folding edge away from an end of the heat dissipation plate, the extension wall extends from the folding edge to a side away from the heat pipe, the folding edge is spaced from the heat pipe, and a gap is defined between a circumferential surface of the folding edge and a circumference of the heat pipe, the extension wall is spaced from the circumference of the heat pipe to form a first containment chamber, and the first containment chamber is communicated with the gap.

2. The heat dissipation device as claimed in claim 1, wherein the plurality of heat fins is stacked in a length direction of the heat pipe.

3. The heat dissipation device as claimed in claim 2, wherein a chamfer is arranged between the folding edge and the heat dissipation plate, the chamfer is spaced from the circumference of the heat pipe, a second containment chamber is formed between the chamfer and the heat pipe, the second containment chamber is communicated with the gap.

4. The heat dissipation device as claimed in claim 3, wherein the chamfer of a heat fin is in contact with an extension wall of an adjacent heat fin, and the second containment chamber of the heat fin is communicated with the first containment chamber of the adjacent heat fin.

5. The heat dissipation device as claimed in claim 1, wherein the gap is 0.1 mm˜0.5 mm.

6. The heat dissipation device as claimed in claim 1, wherein the folding edge is intersected with the extension wall to form a first angle, and the first angle is 130°˜140°.

7. The heat dissipation device as claimed in claim 1, wherein a length of the folding edge is 1 mm˜1.5 mm.

8. The heat dissipation device as claimed in claim 1, wherein the heat-conducting component further comprises a heat-conducting plate and a plurality of heat pipes, including the heat pipe, the plurality of heat pipes is coupled to the heat-conducting plate.

9. The heat dissipation device as claimed in claim 1, further comprising a holder, wherein the holder is arranged to the heat fins.

10. The heat dissipation device as claimed in claim 9, wherein the heat pipe comprises a heat-conducting portion and two heat dissipation portions, the two heat dissipation portions are connected to both ends of the heat-conduction portion, and the holder defines on a storage tank, a tank bottom of the storage tank defines on a penetration hole along a thickness direction of the holder, the heat-conducting portion is matched with the tank bottom, the heat dissipation portion is extended from the storage tank to the plurality of heat fins by the penetration hole.

11. The heat dissipation device as claimed in claim 1, wherein the folding edge is a ring-shaped structure, the folding edge sleeves around the circumference of the heat pipe.

12. The heat dissipation device as claimed in claim 3, wherein the folding edge is extended in the length direction of the heat pipe, the folding edge is arranged between the expansion wall and the chamfer, and the folding edge connects to the expansion wall and the chamfer.

13. A processing method of a heat dissipation device, the processing method comprising:
coating a circumference of a heat pipe with a solid welding material;
stacking a plurality of heat fins in a length direction of the heat pipe;
inserting the heat pipe into heat dissipation plates of the plurality of heat fins through a through-hole;
filling a first containment chamber and a gap with the solid welding material, wherein each of the plurality of heat fins comprises a heat dissipation plate and a folding edge, an extension wall is provided at the folding edge away from an end of the heat dissipation plate, the folding edge and a circumference of the heat pipe are spaced to form the gap, the expansion wall is spaced from the circumference of the heat pipe to form the first containment chamber, the first containment chamber is communicated with the gap; and
heating the heat pipe to melt the solid welding material.

14. The processing method as claimed in claim 13, further comprising:
installing a heat-conducting component, comprising the heat pipe, and the plurality of heat fins to a holder.

15. The processing method as claimed in claim 13, wherein installing the heat-conducting component and the plurality of heat fins to the holder further comprises:
abutting a heat-conducting portion of the heat pipe against a tank bottom of the holder.
